(19) United States
(12) Patent Application Publication
(10) Pub. No.: US 2021/0294150 A1
(43) Pub. Date: Sep. 23, 2021

(54) MANUFACTURING METHOD OF DISPLAY PANEL AND DISPLAY DEVICE

(71) Applicant: WUHAN CHINA STAR OPTOELECTRONICS TECHNOLOGY CO., LTD., Wuhan, Hubei (CN)

(72) Inventor: Zhenhui CHEN, Wuhan, Hubei (CN)

(21) Appl. No.: 16/769,461

(22) PCT Filed: Nov. 8, 2019
(86) PCT No.: PCT/CN2019/116677

§ 371 Date: Jun. 3, 2020

(30) Foreign Application Priority Data
Oct. 25, 2019 (CN) 201911025260.3

(51) Int. Cl. G02F 1/1335; G02F 1/1333; G02F 1/1339

(52) U.S. Cl. CPC G02F 1/133516; G02F 1/133512; G02F 1/1339; G02F 1/133382

(57) ABSTRACT

The present disclosure provides a manufacturing method of a display panel and a display device. A liquid crystal cell is heated to a temperature above a clear point Tni of liquid crystals, and then a mask is provided between ultraviolet light and a color filter substrate. The mask includes a light transmitting area and a light shielding area. The ultraviolet light irradiates the liquid crystal cell through the light transmitting area of the mask. Reactive monomers corresponding to the light transmitting area undergo a polymerization reaction, reactive monomers corresponding to the light shielding area move to the light transmitting area to participate in the polymerization reaction through diffusion, and polymer walls are finally formed in the liquid crystal cell corresponding to the light transmitting area.

### FIELD OF INVENTION

The present disclosure relates to the field of display technologies, and particularly, relates to a manufacturing method of a display panel and a display device.

### BACKGROUND OF INVENTION

Display devices can transform computer data into various characters, numbers, symbols, or intuitive images for display, and can enter commands or data into computers by using an input tool such as a keyboard to add, delete, modify, or change displayed content at any time with help of system hardware and software. Types of the display devices are classified into plasma, liquid crystal, light emitting diode, and cathode ray tube according to the display parts used.

Liquid crystal displays (LCDs) use liquid crystal materials as basic components. The liquid crystal materials are filled between two parallel plates. An arrangement of molecules inside the liquid crystal materials is changed by a voltage to achieve a purpose of light shielding and light transmission, thereby displaying images with different shades. Moreover, by merely adding a ternary color filter layer between the two parallel plates, a colored image can be displayed.

A mainstream of LCDs at present is thin film transistor liquid crystal displays (TFT-LCDs), which have extended from development of original liquid crystal display technology. In an active-type TFT-LCD, each subpixel has a TFT. A gate electrode of the TFT is coupled to a horizontal scanning line, and a drain electrode of the TFT is coupled to a data line in a vertical direction, and a source electrode of the TFT is coupled to a pixel electrode. If a sufficient voltage is applied on the horizontal scanning line, the TFTs on the horizontal scanning line are turned on. At this moment, the pixel electrode on the horizontal scanning line communicate with the data line in the vertical direction, so that a display signal voltage on the data line is written into the pixel. Rotation directions of the liquid crystal molecules are controlled by changing the signal and voltage on the TFT, so as to control whether or not a polarized light of each pixel is emitted to achieve display purpose.

A TFT liquid crystal is provided with a semiconductor switch for each pixel, so as to completely and individually control each pixel point. The liquid crystal materials are sandwiched between a TFT glass layer and a color filter layer, and the rotation directions of the liquid crystal molecules are controlled by changing a voltage value that stimulates the liquid crystals, thereby controlling emission of each pixel's polarized light to achieve the display purpose and controlling an intensity and color of light that finally appears.

### Technical Problems

In the current flexible design, whether thicknesses of the liquid crystal cells are uniform will directly affect a transmission of liquid crystals to an optical path. An application of a supporting member is an important support for maintaining uniform thicknesses of the cells and mechanical stability between flexible plates. Current supporting members are formed by the following: ultraviolet light is used to irradiate an initiator in the liquid crystal materials to induce a generation of free radicals, so that reactive monomers in the liquid crystal materials in a light transmission area undergo radical polymerization, and reactive monomers in a light shielding area move to the light transmission area through diffusion to participate in the polymerization, thereby finally forming polymer walls. In order to form the polymer walls with good uniformity, continuous irradiation of a collimated ultraviolet light source is required. Since the reactive monomers in the liquid crystals move from the light shielding area to the light transmission area, a certain time is required, resulting in a required irradiation time of ultraviolet light being too long, usually reaching 5 minutes. Long irradiation time is not conducive to improving production efficiency, and imposes high challenge to a cooling system of the light source. Taking an exposure machine of CANON as an example, in order to ensure stability of ultraviolet light irradiation, cooling can only be continued after continuous irradiation for about 100 s, and long-term irradiation cannot be achieved. After continuous irradiation for about 100 s, cooling is required to continue working, and prolonged irradiation cannot be achieved. Therefore, a manufacturing method of a new display panel is needed to solve the above problems.

### Technical Solutions

A purpose of the present disclosure is to provide a manufacturing method of a display panel and a display device, which can reduce a moving time of reactive monomers in a light shielding area moving to a light transmission area, thereby improving production efficiency.

To solve the above problems, an embodiment of the present disclosure provides a manufacturing method of a display panel, including following steps: providing an array substrate and a color filter substrate; assembling the array substrate and the color filter substrate, and reserving an injection port; injecting liquid crystal materials between the array substrate and the color filter substrate through the injection port, and sealing the injection port to form a liquid crystal cell; wherein the liquid crystal materials include one or more of liquid crystal molecules and reactive monomers; heating the liquid crystal cell to a temperature that is 0-50° C. above a clear point Tni of liquid crystals; and irradiating the liquid crystal cell with ultraviolet light, so that the liquid crystal materials form polymer walls between the array substrate and the color filter substrate.

Furthermore, the reactive monomers include acrylic monomers containing a carbon-carbon double bond.

Furthermore, the liquid crystal materials further include one or more of initiators and polymerization inhibitors.

Furthermore, the initiators include one or more of an acetophenone initiator, a bisimidazole initiator, a benzoin initiator, a benzophenone initiator, and a quinoxaline initiator.

Furthermore, the polymerization inhibitors include one or more of tert-butylcatechol, p-phenol monobutyl ether, and hydroquinone.

Furthermore, in the step of “heating the liquid crystal cell to a temperature that is 0-50° C. above a clear point Tni of the liquid crystals”, the liquid crystal cell is heated by a heating plate, and the heating plate is positioned on a side of the array substrate away from the color filter substrate; alternatively, the liquid crystal cell is heated by a blast oven, and the blast oven is positioned on a side of the array substrate away from the color filter substrate.

Furthermore, an illuminance of the ultraviolet light 7 is 10-100 mJ/cm².

Furthermore, the manufacturing method of the display panel further includes: providing a mask between the ultraviolet light and the color filter substrate, wherein the mask includes a light transmitting area and a light shielding area, the ultraviolet light irradiates the liquid crystal cell through the light transmitting area of the mask, reactive monomers corresponding to the light transmitting area undergo a polymerization reaction, reactive monomers corresponding to the light shielding area move to the light transmitting area to participate in the polymerization reaction through diffusion, and the polymer walls are finally formed in the liquid crystal cell corresponding to the light transmitting area.

Furthermore, a shape of the light transmitting area of the mask includes one or more shapes of a strip, a grid, and a rectangular array.

Another embodiment of the present disclosure provides a display device including the display panel prepared by the manufacturing method according to the present disclosure.

### BENEFICIAL EFFECT

The present disclosure relates to a manufacturing method of a display panel and a display device. In the present disclosure, the liquid crystal cell is heated to a temperature that is 0-50° C. above a clear point Tni of the liquid crystal. A mask is sandwiched between ultraviolet light and the color filter substrate, the mask has a light transmitting area and a light shielding area, the ultraviolet light irradiates the liquid crystal cell through the light transmitting area, the reactive monomers corresponding to the light transmitting area undergo a polymerization reaction, the reactive monomers corresponding to the light shielding area move to the light transmitting area to participate in the polymerization reaction through diffusion, and polymer walls are finally formed in the liquid crystal cell corresponding to the light transmitting area. The present disclosure accelerates a diffusion and movement speed of the reactive monomers in the liquid crystal materials of the light shielding area, and reduces a time it takes to move from the light shielding area to the light transmitting area, thereby preventing cooling of the reactive monomers and improving production efficiency.

### DESCRIPTION OF DRAWINGS

In order to more clearly illustrate the technical solutions in the embodiments or the prior art, the drawings to be used in the descriptions of the embodiments or the prior art will be briefly described below. Obviously, the drawings in the following description are merely embodiments of the present disclosure. For those of ordinary skill in the art, other drawings may be obtained from the drawings without any creative work.

FIG. 1 is a process diagram of a manufacturing method of a display panel of the present disclosure.

FIG. 2 is a schematic diagram for manufacturing the display panel of the present disclosure.

The components in the figures are identified as follows:

| | |
|---|---|
| 1. array substrate | 2. color filter substrate |
| 3. polymer wall | 4. frame adhesive |
| 5. liquid crystal cell | 6. heating method |
| 7. ultraviolet light | 8. mask |
| 11. first substrate | 12. first functional layer |
| 81. light transmitting area | 82. light shielding area |

### DETAILED DESCRIPTION OF EMBODIMENTS

Preferred embodiments of the present disclosure will be described in detail below with reference to the accompanying drawings in order to completely introduce the technical content of the present disclosure to those skilled in the art, to exemplify that the present disclosure can be implemented, and to make the disclosed technical content of the present disclosure more clear. This makes it easier for those skilled in the art to understand how to implement the present disclosure. However, the present disclosure can be embodied by many different forms of embodiments. A protection scope of the present disclosure is not limited to the embodiments mentioned in the disclosure, and the description of the following embodiments is not intended to limit the scope of the present disclosure.

The orientational terms mentioned in the present disclosure, such as “up”, “down”, “front”, “rear”, “left”, “right”, “inside”, “outside”, “side”, etc., are only the directions in the drawings. The orientational terms used herein are used to explain the present disclosure, rather than to limit the protection scope of the present disclosure.

In the drawings, components having the same structure are denoted by the same numerals, and components having similar structures or functions are denoted by similar numerals. In addition, in order to facilitate understanding and description, a dimension and thickness of each component shown in the drawings are arbitrarily shown, and the present disclosure does not limit the dimension and thickness of each component.

When some of the components are described as being “on” another component, the components may be placed directly on the other component; there may also be an intermediate component that is placed in the middle, the components are placed on the intermediate component, and the intermediate component is placed on the other component. When a component is described as “mounted to” or “connected to” another component, it can be understood as directly “mounted” or “connected”, or the component is indirectly “mounted to” or “connected to” the other component through an intermediate component.

### Embodiment 1

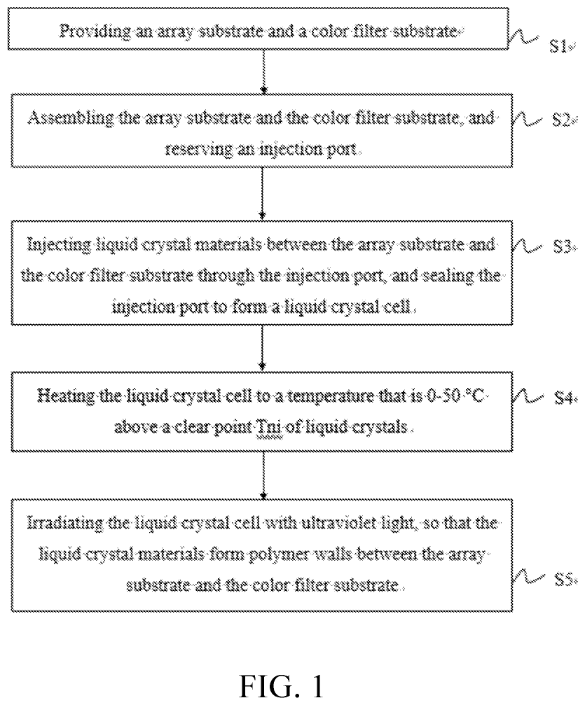

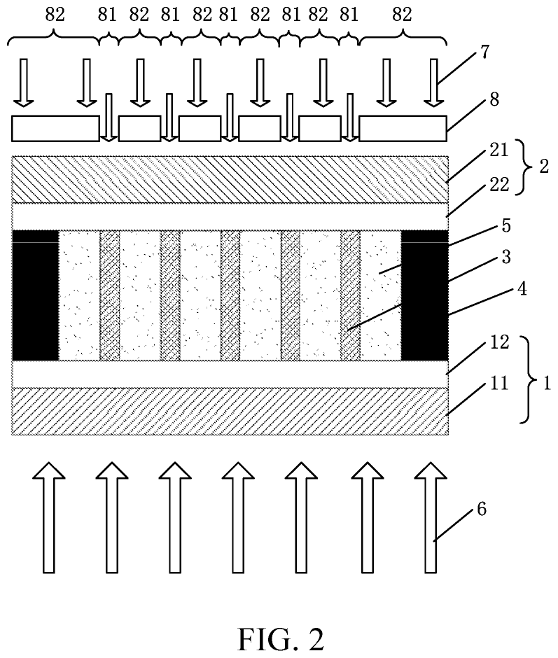

As shown in FIG. 1 and FIG. 2, this embodiment provides a manufacturing method of a display panel 100, including following steps: step S1, providing an array substrate 1 and a color filter substrate 2; step S2, assembling the array substrate 1 and the color filter substrate 2, and reserving an injection port; step S3, injecting liquid crystal materials between the array substrate 1 and the color filter substrate 2 through the injection port, and sealing the injection port to form a liquid crystal cell 5. Actually, a fabrication the liquid crystal cell 5 may also be: applying a frame adhesive 4 on the color filter substrate 2, dripping liquid crystal materials on the array substrate 1, and then coupling the color filter substrate 2 with the frame adhesive 4 to the array substrate 1 with the liquid crystal materials, then irradiating the frame adhesive 4 by ultraviolet light and curing the frame adhesive 4 by heating.

Step S4, heating the liquid crystal cell 5 to a temperature that is 0-50° C. above a clear point Tni of liquid crystals; step S5, irradiating the liquid crystal cell 5 with ultraviolet light 7, so that the liquid crystal materials form polymer walls 3 between the array substrate 1 and the color filter substrate 2.

As shown in FIG. 2, the array substrate 1 in step S1 includes a first substrate 11 and a first functional layer 12 on a surface of the first substrate 11 facing the color filter substrate 2. Herein, the first substrate 11 may be made of flexible materials such as PI, TAC, etc., thereby facilitating formation of a flexible display panel. Wherein, the first functional layer 12 includes structures such as a buffer layer, an active layer, a gate layer, a gate insulating layer, a source drain layer, an interlayer insulating layer, etc., which are not described.

As shown in FIG. 2, the color filter substrate 2 in the step S1 includes a second substrate 21 disposed correspondingly to the first substrate 11 and a second functional layer 22 disposed on a surface of the second substrate 21 facing the first substrate 11. Wherein, the second substrate 21 may be made of flexible materials such as PI, TAC, etc., thereby facilitating the formation of a flexible display panel. Wherein, the second functional layer 22 includes structures such as a black matrix, a color filter, etc., which are not described.

As shown in FIG. 2, in the step S2, the array substrate 1 and the color filter substrate 2 are assembled through a frame adhesive 4. The frame adhesive 4 is sandwiched between the array substrate 1 and the color filter substrate 2. The frame adhesive 4 mainly plays a supporting role and facilitates later injection of the liquid crystal materials.

The liquid crystal materials in step S3 include one or more of liquid crystal molecules, reactive monomers, initiators, and polymerization inhibitors.

Wherein, the reactive monomers include acrylic monomers containing a carbon-carbon double bond. The reactive monomers are mainly used to polymerize with free radicals generated after the initiator is irradiated with ultraviolet light to form the polymer walls 3.

Wherein, the initiators include one or more of an acetophenone initiator, a bisimidazole initiator, a benzoin initiator, a benzophenone initiator, and a quinoxaline initiator. The initiators mainly generate free radicals after being irradiated with ultraviolet light, which facilitates the reactive monomers to polymerize with the free radicals generated after being irradiated to form the polymer walls 3.

Wherein, the polymerization inhibitors include one or more of a tert-butylcatechol, a p-phenol monobutyl ether, and a hydroquinone. The polymerization inhibitors are mainly used to prevent polymerization.

As shown in FIG. 2, in the step S4, the liquid crystal cell 5 is heated by a heating plate, and the heating plate is positioned on the side of the array substrate 1 away from the color filter substrate 2; alternatively, the liquid crystal cell 5 is heated by a blast oven, and the blast oven is positioned on a side of the array substrate 1 away from the color filter substrate 2. Wherein, in the step 4, the liquid crystal cell may also be heated by infrared heating or pulse heating. Wherein, detailed structures of the heating plate and the blast oven are not described. Since thermal diffusion is related to a temperature of a liquid, the higher the temperature, the greater an energy is, the easily migration occurs, the larger a diffusion coefficient is, and the faster diffusion is. Moreover, as the temperature of the liquid crystal materials increases, viscosity will be significantly reduced, which is beneficial to the diffusion of the reactive monomers. Therefore, heating the liquid crystal materials in the liquid crystal cell 5 is beneficial for reducing the viscosity of the liquid crystal materials, which facilitates the reactive monomers in a light shielding area 82 to move to an irradiation area 81 through diffusion to participate in the polymerization reaction, thereby reducing a moving time, and improving production efficiency.

In the step S4, the liquid crystal cell 5 is heated to a temperature that is 0-50° C. above a clear point Tni of the liquid crystal. Specifically, if the Tni of the liquid crystals is 85° C., the liquid crystal cell 5 is heated to a temperature of 85-135° C., preferably 85-90° C. This will cause the liquid crystal materials to undergo a transition from a liquid crystal phase to an amorphous phase, and the viscosity will be significantly reduced, which is beneficial to the diffusion of the reactive monomers.

As shown in FIG. 2, the step S5 includes: providing a mask 8 between the ultraviolet light 7 and the color filter substrate 2. The mask 8 has a light transmitting area 81 and a light shielding area 82. The ultraviolet light 7 irradiates the liquid crystal cell 5 through the light transmitting area 81. Wherein, the reactive monomers corresponding to the light transmitting area 81 undergo a polymerization reaction, the reactive monomers corresponding to the light shielding area 82 move to the light transmitting area 81 to participate in the polymerization reaction through diffusion, and polymer walls 3 are finally formed in the liquid crystal cell 5 corresponding to the light transmitting area 81. Wherein, the polymer walls 3 mainly ensure uniformity of a thickness of the liquid crystal cell 5 and plays a supporting and stabilizing role, which is an important basis for achieving high-quality display effect. Specifically, an illuminance of the ultraviolet light 7 is 10-100 mJ/cm².

Wherein, a shape of the light transmitting area 81 of the mask 8 includes one or more shapes of a strip, a grid, and a rectangular array. A particular shape is decided according to an actual situation.

The manufacturing method of a display panel shown in FIG. 1 and FIG. 2 accelerates a diffusion and movement speed of the reactive monomers in the liquid crystal materials of the light shielding area 82, and reduces a time it takes to move from the light shielding area 82 to the light transmitting area 81, thereby preventing cooling of the reactive monomers and improving production efficiency.

As shown in FIG. 2, in this embodiment, the liquid crystal cell 5 is heated on a side of the array substrate 1 away from the color filter substrate 2, and the liquid crystal cell 5 is irradiated with light on a side of the color film substrate 2 away from the array substrate 1. In fact, we can also heat the liquid crystal cell 5 on a side of the color filter substrate 2 away from the array substrate 1, and irradiate the liquid crystal cell 5 with light on a side of the array substrate 1 away from the color filter substrate 2. A specific operation can be determined according to the actual situation.

The present disclosure also provides a display device which includes a display panel prepared by the manufacturing method for a display panel according to the present disclosure.

The manufacturing method of a display panel and the display device provided by the present disclosure have been described in detail above. It should be understood that the exemplary embodiments described herein should be considered only descriptive, to help understand the method of the present disclosure and its core ideas, and not to limit the present disclosure. Descriptions of features or aspects in each exemplary embodiment should generally be considered as applicable to similar features or aspects in other exemplary embodiments. Although the present disclosure has been described with reference to exemplary embodiments, various changes and modifications may be suggested to one skilled in the art. The present disclosure is intended to cover these changes and modifications within a scope of the appended claims, and any modification, equivalent replacement, and improvement made within the spirit and principle of the present disclosure shall be included in the protection of the present disclosure.

1. A manufacturing method of a display panel, comprising following steps:
providing an array substrate and a color filter substrate;
assembling the array substrate and the color filter substrate, and reserving an injection port;
injecting liquid crystal materials between the array substrate and the color filter substrate through the injection port, and sealing the injection port to form a liquid crystal cell;
wherein the liquid crystal materials comprise one or more of liquid crystal molecules and reactive monomers;
heating the liquid crystal cell to a temperature that is 0-50° C. above a clear point Tni of liquid crystals; and
irradiating the liquid crystal cell with ultraviolet light, so that the liquid crystal materials form polymer walls between the array substrate and the color filter substrate.

2. The manufacturing method of the display panel as claimed in claim 1, wherein the reactive monomers comprise acrylic monomers containing a carbon-carbon double bond.

3. The manufacturing method of the display panel as claimed in claim 1, wherein the liquid crystal materials further comprise one or more of initiators and polymerization inhibitors.

4. The manufacturing method of the display panel as claimed in claim 3, wherein the initiators comprise one or more of an acetophenone initiator, a bisimidazole initiator, a benzoin initiator, a benzophenone initiator, and a quinoxaline initiator.

5. The manufacturing method of the display panel as claimed in claim 3, wherein the polymerization inhibitors comprise one or more of tert-butylcatechol, p-phenol monobutyl ether, and hydroquinone.

6. The manufacturing method of the display panel as claimed in claim 1, wherein in the step of “heating the liquid crystal cell to a temperature that is 0-50° C. above a clear point Tni of the liquid crystals”,
the liquid crystal cell is heated by a heating plate, and the heating plate is positioned on a side of the array substrate away from the color filter substrate; or
the liquid crystal cell is heated by a blast oven, and the blast oven is positioned on the side of the array substrate away from the color filter substrate.

7. The manufacturing method of the display panel as claimed in claim 1, wherein an illuminance of the ultraviolet light 7 is 10-100 mJ/cm².

8. The manufacturing method of the display panel as claimed in claim 3, further comprising; providing a mask between the ultraviolet light and the color filter substrate, wherein the mask comprises a light transmitting area and a light shielding area, the ultraviolet light irradiates the liquid crystal cell through the light transmitting area of the mask, reactive monomers corresponding to the light transmitting area undergo a polymerization reaction, reactive monomers corresponding to the light shielding area move to the light transmitting area to participate in the polymerization reaction through diffusion, and the polymer walls are finally formed in the liquid crystal cell corresponding to the light transmitting area.

9. The manufacturing method of the display panel as claimed in claim 8, wherein a shape of the light transmitting area of the mask comprises one or more shapes of a strip, a grid, and a rectangular array.

10. A display device, comprising a display panel prepared by a manufacturing method of the display panel, wherein the manufacturing method of the display panel comprises:
providing an array substrate and a color filter substrate;
assembling the array substrate and the color filter substrate, and reserving an injection port;
injecting liquid crystal materials between the array substrate and the color filter substrate through the injection port, and sealing the injection port to form a liquid crystal cell;
wherein the liquid crystal materials comprise one or more of liquid crystal molecules and reactive monomers;
heating the liquid crystal cell to a temperature that is 0-50° C. above a clear point Tni of liquid crystals; and
irradiating the liquid crystal cell with ultraviolet light, so that the liquid crystal materials form polymer walls between the array substrate and the color filter substrate.

11. The display device as claimed in claim 10, wherein the reactive monomers comprise acrylic monomers containing a carbon-carbon double bond.

12. The display device as claimed in claim 10, wherein the liquid crystal materials further comprise one or more of initiators and polymerization inhibitors.

13. The display device as claimed in claim 12, wherein the initiators comprise one or more of an acetophenone initiator, a bisimidazole initiator, a benzoin initiator, a benzophenone initiator, and a quinoxaline initiator.

14. The display device as claimed in claim 12, wherein the polymerization inhibitors comprise one or more of tert-butylcatechol, p-phenol monobutyl ether, and hydroquinone.

15. The display device as claimed in claim 10, wherein in the step of “heating the liquid crystal cell to a temperature that is 0-50° C. above a clear point Tni of the liquid crystals”,
the liquid crystal cell is heated by a heating plate, and the heating plate is positioned on a side of the array substrate away from the color filter substrate; or
the liquid crystal cell is heated by a blast oven, and the blast oven is positioned on the side of the array substrate away from the color filter substrate.

16. The display device as claimed in claim 10, wherein an illuminance of the ultraviolet light 7 is 10-100 mJ/cm².

17. The display device as claimed in claim 12, wherein the manufacturing method of the display panel further comprises providing a mask between the ultraviolet light and the color filter substrate, wherein the mask comprises a light transmitting area and a light shielding area, the ultraviolet light irradiates the liquid crystal cell through the light transmitting area of the mask, reactive monomers corresponding to the light transmitting area undergo a polymerization reaction, reactive monomers corresponding to the light shielding area move to the light transmitting area to participate in the polymerization reaction through diffusion, and the polymer walls are finally formed in the liquid crystal cell corresponding to the light transmitting area.

18. The display device as claimed in claim 17, wherein a shape of the light transmitting area of the mask comprises one or more shapes of a strip, a grid, and a rectangular array.
